(19) United States
(12) Patent Application Publication
(10) Pub. No.: US 2014/0252490 A1
(43) Pub. Date: Sep. 11, 2014

(54) SEMICONDUCTOR DEVICE AND METHOD OF MANUFACTURING THE SEMICONDUCTOR DEVICE

(71) Applicant: FUJITSU SEMICONDUCTOR LIMITED, Yokohama-shi (JP)

(72) Inventors: Akihiro Usujima, Hachioji (JP); Masamichi Kamiyama, Hachioji (JP); Yasumori Miyazaki, Akiruno (JP)

(73) Assignee: FUJITSU SEMICONDUCTOR LIMITED, Yokohama-shi (JP)

(21) Appl. No.: 14/139,050

(22) Filed: Dec. 23, 2013

(30) Foreign Application Priority Data
Mar. 6, 2013 (JP) 2013-044142

(51) Int. Cl. H01L 27/088

(52) U.S. Cl. CPC H01L 27/088
USPC 257/368; 438/296

(57) ABSTRACT

Disclosed is a semiconductor device including a semiconductor device including a substrate, a nitride semiconductor layer formed over the substrate and including an active region and an element isolation region, inert atoms being introduced into the element isolation region, a source electrode formed over the nitride semiconductor layer in the active region, a gate electrode formed over the nitride semiconductor layer in the active region away from the source electrode, and a drain electrode formed over the nitride semiconductor layer in the active region away from the gate electrode, the drain electrode including an end portion provided away from a boundary between the element isolation region and the active region by a first distance, wherein the first distance is greater than a second distance, the second distance being a distance where a concentration of the inert atoms diffused from the element isolation region into the active region becomes a first concentration, and an electron density in the active region at a position where the concentration of the inert atoms is higher than the first concentration is lower than an electron density in a center portion of the active region.

### CROSS-REFERENCE TO RELATED APPLICATION

This application is based upon and claims the benefit of priority of the prior Japanese Patent. Application No. 2013-044142, filed on Mar. 6, 2013, the entire contents of which are incorporated herein by reference.

### FIELD

The embodiments discussed herein are related to a semiconductor device and a method of manufacturing the semiconductor device.

### BACKGROUND

Exploiting an advantage of the high withstand voltage, a field effect transistor using a nitride semiconductor such as gallium nitride for a channel is applied to high-output device. One of factors reducing the withstand voltage of the field effect transistor is electric field concentration at drain ends. Reducing this electric field concentration can further improve the withstand voltage of the field effect transistor.

However, the field effect transistor can be further improved by finding factors dominating the withstand voltage other than the electric field concentration at the drain ends to further improve the withstand voltage.

Technologies related to the present application are disclosed in Japanese Laid-open Patent Publication No. 2010-238982 and Japanese Laid-open Patent Publication No. 2010-62321.

### SUMMARY

According to one aspect discussed herein, there is provided a semiconductor device including a substrate, a nitride semiconductor layer formed over the substrate and including an active region and an element isolation region, inert atoms being introduced into the element isolation region, a source electrode formed over the nitride semiconductor layer in the active region, a gate electrode formed over the nitride semiconductor layer in the active region away from the source electrode and a drain electrode formed over the nitride semiconductor layer in the active region away from the gate electrode, the drain electrode including an end portion provided away from a boundary between the element isolation region and the active region by a first distance, wherein the first distance is greater than a second distance, the second distance being a distance where a concentration of the inert atoms diffused from the element isolation region into the active region becomes a first concentration, and an electron density in the active region at a position where the concentration of the inert atoms is higher than the first concentration is lower than an electron density in a center portion of the active region.

According to another aspect discussed herein, there is provided a semiconductor device including a substrate, a nitride semiconductor layer formed over the substrate and including an active region and an element isolation region, inert atoms being introduced into the element isolation region, a source electrode formed over the nitride semiconductor layer in the active region, a drain electrode formed over the nitride semiconductor layer in the active region away from the source electrode, the drain electrode including an end portion provided away from a boundary between the element isolation region and the active region by a first distance, and a gate electrode formed over the nitride semiconductor layer in the active region away from the element isolation region and including a first opening and a second opening, the source electrode being in the first opening, the second opening being provided away from the first opening, the drain electrode being in the second opening, wherein the first distance is greater than a second distance, the second distance being a distance where a concentration of the inert atoms diffused from the element isolation region into the active region becomes a first concentration, and an electron density in the active region at a position where the concentration of the inert atoms is higher than the first concentration is lower than an electron density in a center portion of the active region.

The object and advantages of the invention will be realized and attained by means of the elements and combinations particularly pointed out in the claim.

It is to be understood that both the forgoing general description and the following detailed description are exemplary and explanatory and are not restrictive of the invention.

### BRIEF DESCRIPTION OF THE DRAWINGS

FIG. 1A is an enlarged plan view of a field effect transistor used in research;

FIG. 1B is a cross-sectional view taken along the I-I line of FIG. 1A;

FIG. 2 is a plan view schematically illustrating how a depletion layer is affected by difference in an electron density in an active region;

FIG. 3A is a graph obtained by simulating the electron density in the active region;

FIG. 3B is a graph obtained by simulating electric field strength;

FIG. 4A is a cross-sectional view (part 1) taken along a channel length direction in a course of switching the field effect transistor from off state to on state;

FIG. 4B is a cross-sectional view (part 2) taken along the channel length direction in the course of switching the field effect transistor from off state to on state;

FIG. 5A is a plan view of a semiconductor device in a first embodiment;

FIG. 5B is a cross-sectional view taken along the line of FIG. 5A;

FIG. 6 is a view obtained by simulating concentration distribution of argon atoms in the first embodiment;

FIG. 7 is a view obtained by simulating the concentration of argon atoms in a surface of a channel layer in the first embodiment;

FIG. 8A is view obtained by examining the withstand voltage of a field effect transistor according to a comparative example;

FIG. 8B is view obtained by examining the withstand voltage of a field effect transistor according to a first embodiment;

FIG. 9 is a plan view illustrating displacement between an element isolation region and a drain electrode in the first embodiment;

FIGS. 10A to 10M are cross-sectional views of the semiconductor device in the course of manufacturing thereof according to the first embodiment;

FIG. 11 is a plan view of a semiconductor device according to a second embodiment;

FIG. 12A is a plan view of a semiconductor device according to a third embodiment;

FIG. 12B is an enlarged plan view of one of end portions of a drain electrode in a semiconductor device according to the third embodiment;

FIG. 13 is a plan view of a semiconductor device according to a fourth embodiment; and

FIG. 14 is a plan view of a semiconductor device according to a fifth embodiment.

### DESCRIPTION OF EMBODIMENTS

Prior to explaining the present embodiments, research conducted by the inventors of the present application is described.

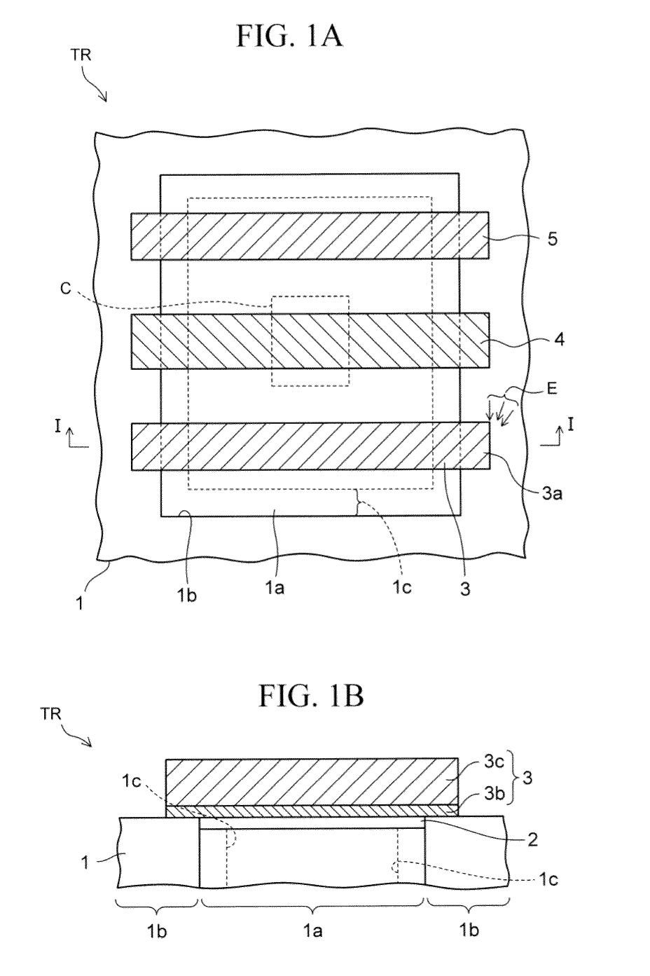

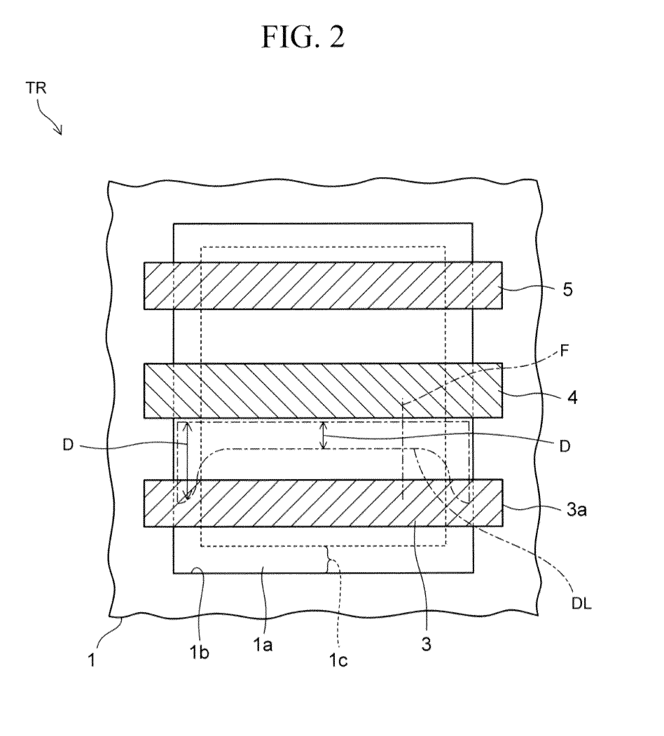

FIG. 1A is an enlarged plan view of a field effect transistor used in the research. As illustrated in FIG. 1A, this field effect transistor TR includes a channel layer 1. Moreover, the field effect transistor TR includes a drain electrode 3, a gate electrode 4, and a source electrode 5 which are formed on the channel layer 1 away from each other.

Among them, as for the channel layer 1, a nitride semiconductor layer such as a gallium nitride layer preferable for increasing the withstand voltage of the field effect transistor TR can be used. The channel layer 1 has an active region 1a rectangular in a plan view. The channel layer 1 surrounding the active region 1a is served as an element isolation region 1b, into which ions of argon atoms are implanted and which thus has a low electron density.

In such a method of forming the element isolation region 1b by ion implantation, there is no need to isolate elements by forming trenches and insulating films as in STI (Shallow Trench Isolation) and the like. Hence, manufacturing steps of a semiconductor device can be simplified.

Here, each of end portions 3a of the drain electrode 3 is a portion where an electric field E tends to concentrate. Since occurrence of such electric field concentration in the active region 1a may cause the withstand voltage of the transistor TR to decrease, the end portions 3a are provided on the element isolation region 1b in this example.

FIG. 1B is a cross-sectional view taken along the I-1 line of FIG. 1A.

As illustrated in FIG. 1B, the drain electrode 3 is formed by stacking an underlying conductive layer 3b which has a low work function like a titanium nitride layer and a conductive layer 3c such as an aluminum layer which is a main body portion of the electrode, in this order.

Moreover, an AlGaN layer is provided between the channel layer 1 and the drain electrode 3 as an electron supplying layer 2. Note, that the electron supplying layer 2. is omitted in FIG. 1A.

As described above, ions of argon are implanted into the element isolation region 1b. Since this ion implantation destroys a crystal structure of the channel layer 1 in the element isolation region 1b, the electron density in the element isolation region 1b becomes lower than that in the active region 1a, so that the adjacent field effect transistors TR can be electrically isolated from each other.

However, since a few of the ions of argon implanted into the element isolation region 1b scatter in the channel layer 1 in the ion implantation, and are thus introduced into the active region 1a, argon exists also in a region 1c indicated by dotted lines in FIGS. 1A and 1B.

The electron density in the region 1c becomes lower than that in a center portion C. (see FIG. 1A) of the active region 1a due to the crystal breakage in the channel layer 1 which is caused by argon.

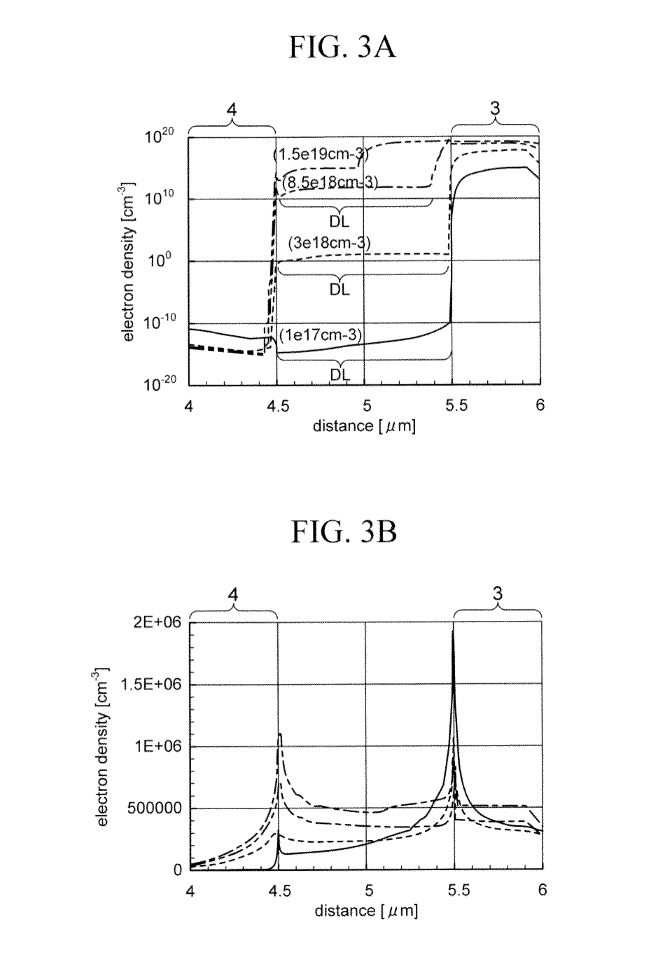

FIG. 2 is a plan view schematically.

illustrating how a depletion layer is affected by such difference in electron density in the active region 1a.

Note that elements in FIG. 2 which are the same as those in FIGS. 1A and 1B are denoted by the same reference numerals as those in FIGS. 1A and 1B, and description thereof is omitted below.

FIG. 2 illustrates the case where a transistor TR is set to off by setting a gate voltage Vg to a low level of about 0 V with a drain voltage Vd maintained at a high level of about 25 V.

In this case, a depletion layer DL spreads in the channel layer 1 between the drain electrode 3 and the gate electrode 4. In the channel layer 1, depletion occurs faster in a region where the electron density is smaller. Accordingly, the width D of the depletion layer DL becomes larger in a portion closer to the region 1c in the active region 1a, and hence the width D differs depending on the position in the active, region 1a.

The inventors of the present application conducted the following research on the effect of the difference in the width D of the depletion layer DL on the withstand voltage of the field effect transistor TR.

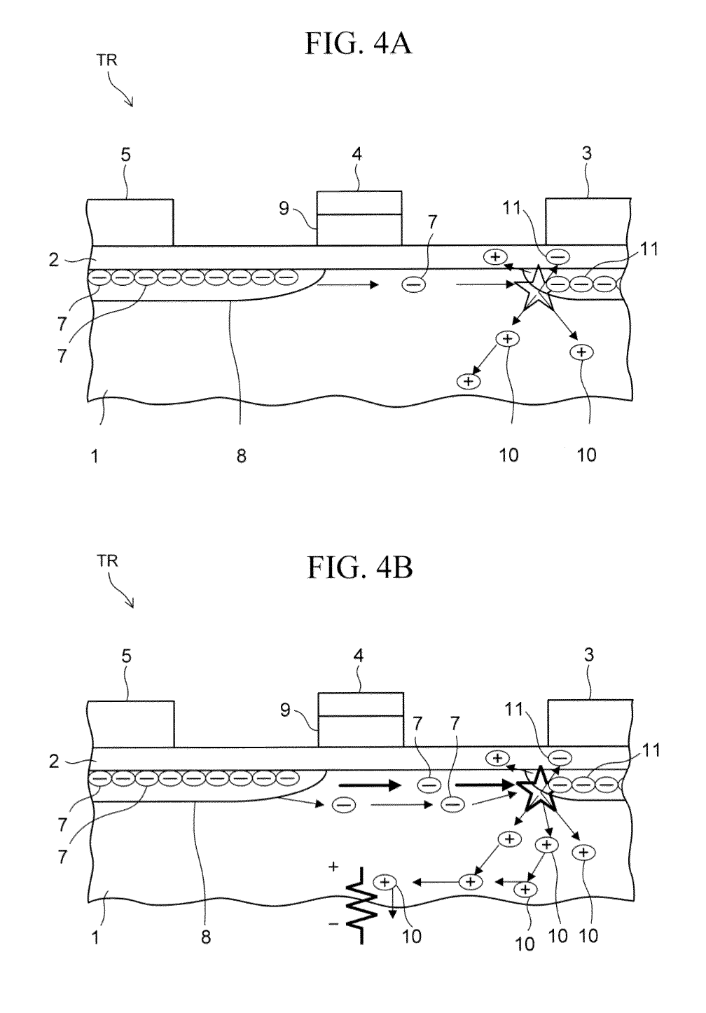

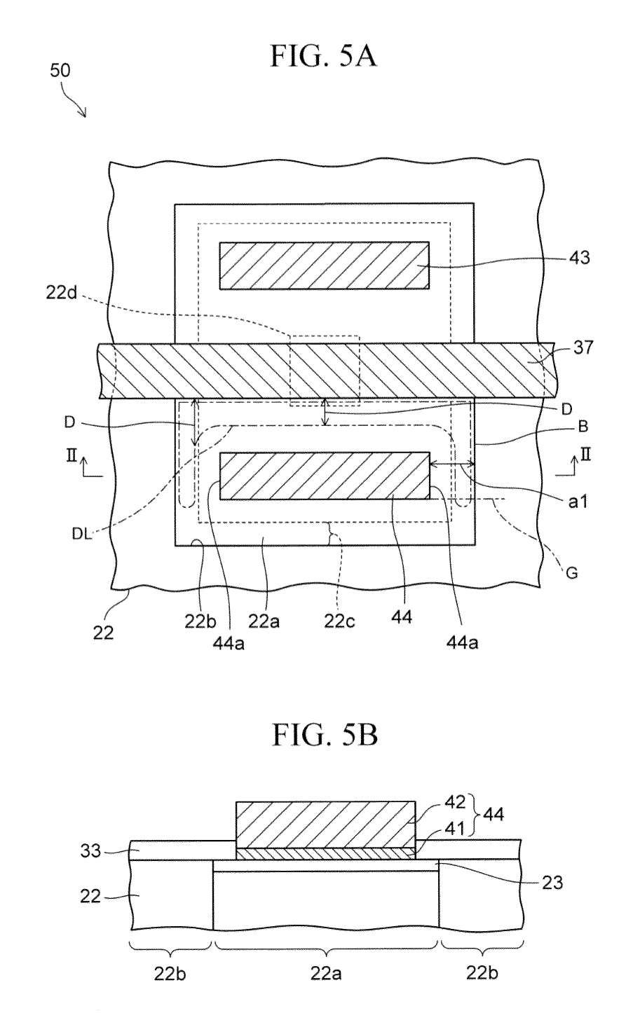

FIG. 3A is a graph obtained by simulating the electron density in the active region 1a.

In this simulation, there is calculated the electron density along the cross-section line F of FIG. 2 in the case where the gate voltage Vg is 0 V and the drain voltage Vd is 25 V.

The horizontal axis of FIG. 3A indicates the distance from an origin in the gate electrode 4 along the cross-section line F, and the vertical axis thereof indicates the electron density in the active region 1a.

FIG. 3A includes a plurality of graphs because the simulation is performed a plurality of times while varying the electron density in the case where the drain voltage Vd is 0V. A numeric value in parentheses of each graph indicates the electron density in the case of Vd=0 V.

As illustrated in FIG. 3A, it is confirmed also from the simulation that the smaller the electron density in the case of Vd=0 V is, the closer the depletion layer DL in the case of Vd=25 V is to the drain electrode 3 and the larger the width D of the depletion layer DL is.

FIG. 3B is a graph obtained by simulating electric field strength along the cross-section line F of FIG. 2 for each value of the electron density in the case of Vd=0 V.

The values of the electron density in the case of Vd=0 V are the same values as those in FIG. 3A, and the graph of the electron density of the same value is illustrated by the same type of line as that in FIG. 3A.

Moreover, the horizontal axis of FIG. 3B is the same as the horizontal axis of FIG. 3A, and the vertical axis indicates the electric field strength.

As illustrated in FIG. 3B, for example, when the electron density in the case of Vd=0 V is large as illustrated by the graph of the one-dot chain line, the electric field strength in the drain electrode 3 is small.

On the other hand, it is found that, when the electron density in the case of Vd=0 V is small as illustrated by the graph of the solid line, the electric field strength in the drain electrode 3 becomes large.

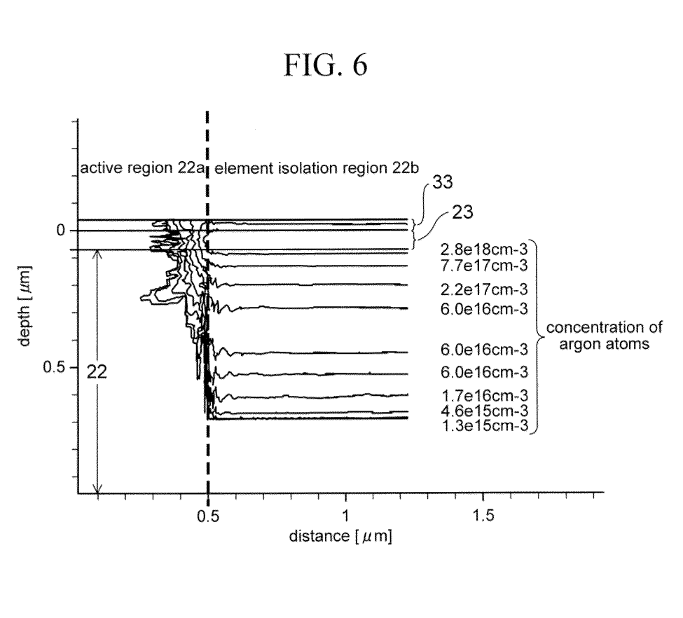

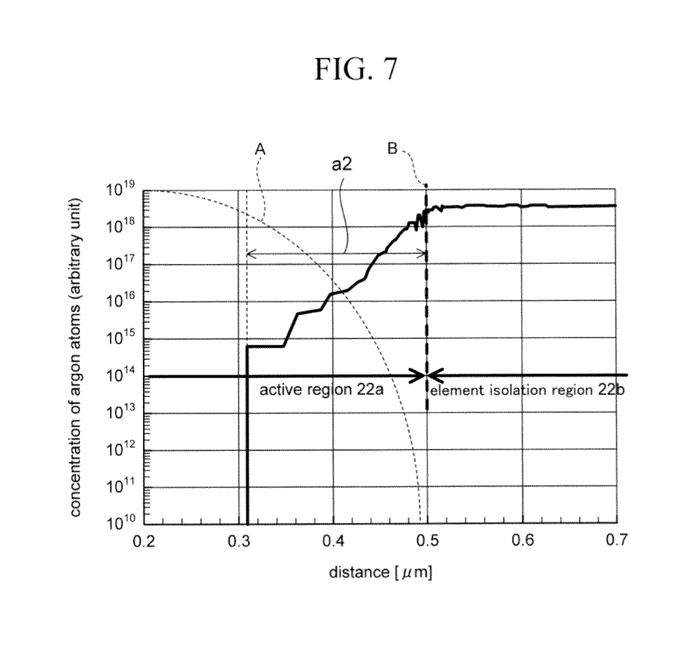

FIGS. 4A and 4B are cross-sectional views schematically illustrating that the withstand voltage of the field effect transistor TR decreases due to such electric field concentration in the drain electrode 3. Note that elements in FIGS. 4A and 4B which are the same as those described in FIGS. 1A, 1B, and 2 are denoted by the same reference numerals as those in FIGS. 1A, 1B, and 2, and description thereof is omitted below.

FIG. 4A is a cross-sectional view taken along a channel length direction in a course of switching the field effect transistor TR from off to on.

As illustrated in FIG. 4A, a p-type GaN layer is provided between the electron supplying layer 2 and the gate electrode 4 as a cap layer 9.

Electrons 7 are induced by AlGaN of the electron supplying layer 2, in an interface between the channel layer 1 and the electron supplying layer 2 close to the source electrode 5, and a two-dimensional electron was 8 is generated by the electrons 7.

When the gate voltage is 0 V, the aforementioned cap layer 9 acts in such a way as to reduce the potential of the electron supplying layer 2 below the cap layer 9. Thus, no two-dimensional electron gas 8 is generated below the gate electrode 4, and the field effect transistor TR is set to off.

Here, in the course of raising the gate voltage and switching the field effect transistor TR from off to on, the electrons 7 are pulled from the aforementioned two-dimensional electron as 8 toward the drain electrode, 3.

At this time, when the electric field strength in the drain electrode 3 is strong as described above, the electrons 7 are accelerated by the strong electric field to have high energy. Then, the high-energy electrons 7 collide with a crystal lattice of GaN in the channel layer 1 in a portion near the drain electrode 3.

Since, the high-energy electrons 7 give high energy to electrons 11 in a covalent bond of GaN in this collision, the electrons 11 turn into free electrons and holes 10 corresponding to the electrons 11 are generated. Such generation of pairs of electrons and holes is referred also to as ion impact.

As illustrated in FIG. 4B, although the electrons 11 generated in the ion impact are taken out from the drain electrode 3, the holes 10 gradually accumulate in the channel layer 1. Since these holes raise the potential of the channel layer 1, the electrons 7 are pulled out from the two-dimensional electron gas 8, and the pulled-out electrons 7 flow toward the drain electrode 3 to cause further ion impact.

The ion impact by the electron 7 thus enters a positive feedback loop and eventually causes avalanche breakdown, thereby causing significant deterioration in the withstand voltage of the field effect transistor TR.

As described above, this example aims to increase the withstand voltage of the transistor TR by positioning the end portions 3a of the drain electrode 3 on the element isolation region 1b as illustrated in FIG. 1A so that the electric field concentration to the end portions 3a does not occur in the active region 1a.

However, in an actual case, the region 1c in which the electron density is low due to argon diffused from the element isolation region 1b is formed in the active region 1a as described above, and the electric field is intensively concentrated in a portion of the drain electrode 3 which overlap the region 1c, thereby causing the withstand voltage of the transistor TR to decrease.

In the following, description is given of a field effect transistor capable of suppressing the decrease of the withstand voltage even when inert atoms such as argon are diffused as described above.

### FIRST EMBODIMENT

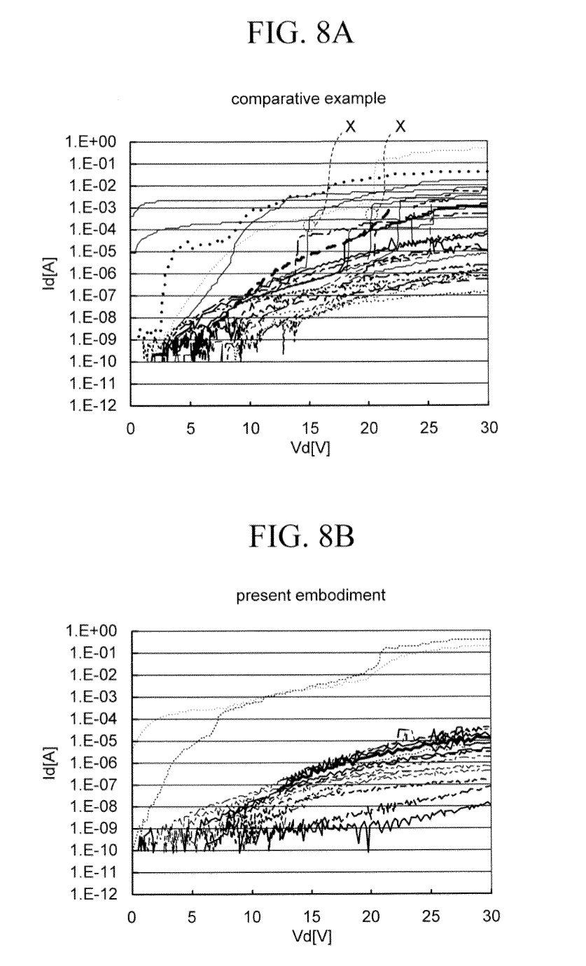

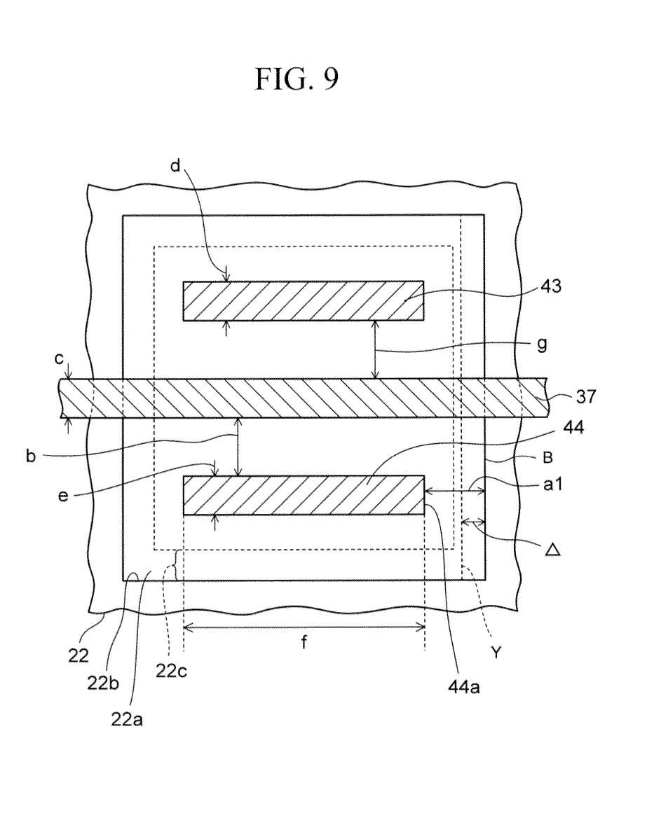

FIG. 5A is a plan view of a semiconductor device in a first embodiment.

The semiconductor device 50 is a field effect transistor including a channel layer 22 made of a nitride semiconductor that is advantageous for achieving a high withstand voltage. The semiconductor device 50 has a source electrode 43, a gate electrode 37, and a drain electrode 44 which are formed on the channel layer 22 away from each other. Note that the channel layer 22 is an example of a nitride semiconductor layer.

Gallium nitride is used as the nitride semiconductor which is the material of the channel layer 22. The channel. layer 22 has an active, region 22a rectangular in a plan view and an element isolation region 22b surrounding the active region 22a.

Argon atoms are ion-implanted into the channel layer 22 in the element isolation region 22b as inert atoms. The argon atoms destroy a gallium nitride crystal in the element isolation region 22b, and hence the electron density in the element isolation region 22b can be reduced.

As described above, since a few of the ions of argon implanted into the element isolation region 22b scatter in the channel layer 22 in the ion implantation and are introduced into the active region 22a, argon exists also in a region 22c indicated by dotted lines.

The electron density in the region 22c is smaller than that in a center portion 22d of the active region 22a due to the aforementioned argon. Such difference in electron density causes the width D of a depletion layer DL to differ depending on the position in the active region 22a as described above, and the width D is particularly increased in the region 22c.

When the region 22c having a particularly low electron density overlaps the drain electrode 44, the electric field strength increases in the drain electrode 44 as illustrated in FIG. 3B, and the withstand voltage of the field effect transistor decreases.

To deal with this problem, in the embodiment, the region 22c and end portion 44a of the drain electrode 44 are prevented from overlapping one another by setting back the end portion 44a from a boundary B between the active region 22a and the element isolation region 22b, so that the withstand voltage of the field effect transistor is thereby increased.

Setting back the end portion 44a from the boundary B in this manner causes the boundary B and the end portion 44a to be spaced away by a first distance a1. A preferable, value of the first distance a1 will be described later.

FIG. 5B is a cross-sectional view taken along the II-II line of FIG. 5A.

As illustrated in FIG. 5B, an AlGaN layer is provided on the active, region 22a as an electron supplying layer 23.

Moreover, the drain electrode 44 is formed by stacking an underlying conductive layer 41 such as a titanium nitride layer and a conductive layer 42 such as an aluminum layer which is a main body portion of the electrode, in this order.

Furthermore, the channel layer 22 and the electron supplying layer 23 beside the drain electrode 44 are protected by a protection insulating layer 33 such as a silicon nitride layer.

Next, description is given of the preferable value of the first distance a1 between the boundary B and the end portion 44a of the drain electrode 44 illustrated in FIG. 5A.

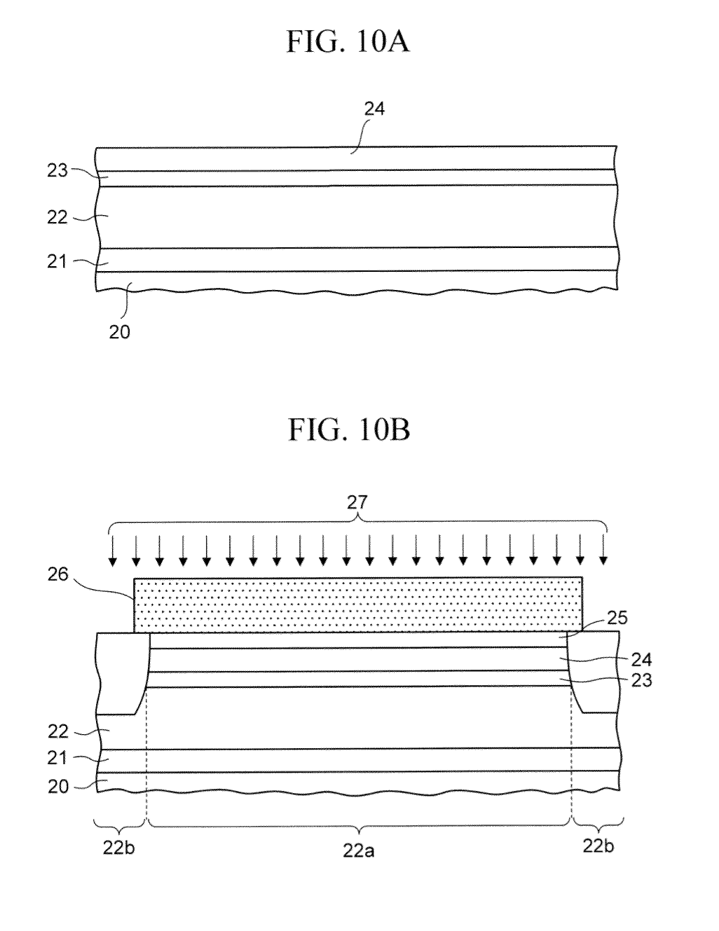

FIG. 6 is a view obtained by simulating the concentration distribution of argon atoms along the cross-section line C of FIG. 5A by using a Monte Carlo method. The horizontal axis of FIG. 6 indicates a distance along the cross-section line G in the case where the end portion 44a of the drain electrode 44 is set as an origin. The vertical axis of FIG. 6 indicates a depth measured from a surface of the protection insulating layer 33.

In FIG. 6, points of the same concentration of argon atoms are plotted, and a plurality of concentration distributions are illustrated for each of concentrations. Numeric values beside the concentration distributions indicate the concentrations of argon atoms corresponding to the distributions.

As illustrated in FIG. 6, the argon atoms are diffused from the element isolation region 22b into the active region 22a.

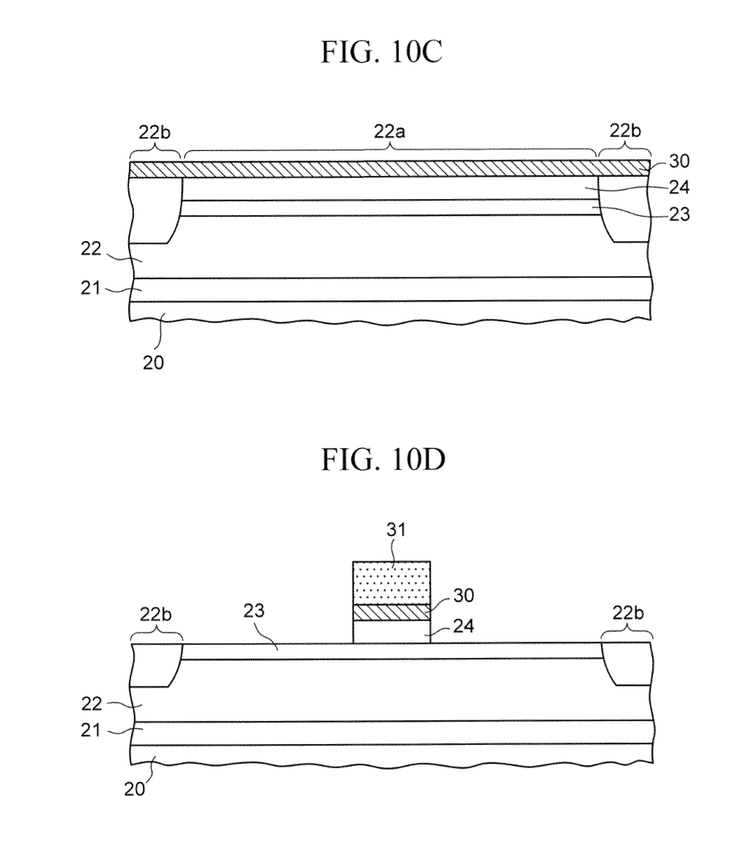

FIG. 7 is a view obtained by simulating the concentration of argon atoms in a surface of the channel layer 22. The horizontal axis of FIG. 7 indicates the distance along the cross-section line G in the case where the end portion 44a of the drain electrode 44 is set as the origin, as in FIG. 6. Moreover, the vertical axis of FIG. 7 indicates the concentration of argon atoms in the surface of the channel layer 22.

As illustrated in FIG. 7, the argon atoms are diffused from the element isolation region 22b into the active region 22a also in the surface of the channel layer 22.

As described above, the electron density decreases in the region in which the argon atoms are diffused. In FIG. 7, since the concentration of argon atoms is low in a portion of the active region 22a which is spaced away from the boundary B, no significant decrease of the electron density occurs in this portion.

The graph A which is illustrated by the dotted line in FIG. 7 is a graph schematically illustrating such an electron density. As illustrated by the graph A, the electron density has a sufficiently large value in the portion of the active region 22a which is spaced away from the boundary B.

In the portion where the electron density is large in this manner, the electric field concentration in the drain electrode is suppressed as illustrated in FIG. 3B. Accordingly, setting back the end portion 44a of the drain electrode 44 to the portions where the electron density is large can prevent the electric field concentration to the drain electrode 44.

Therefore, in the present embodiment, an electron density E_{D} in the center portion 22d (see FIG. 5A) of the active region 22a is used as a reference of an electron density capable of suppressing the electric field concentration to the drain electrode 44, and the end portion 44a is set back to regions in which the electron density is equal to the electron density E_{D}.

In FIG. 7, the concentration of argon atoms sharply decreases in the case where the distance is equal to or smaller than 0.31 μm. Hence, in a region where the distance is equal to or smaller than 0.31 μm, the amount of argon diffused from the element isolation region 22b is small enough to be ignorable, and the concentration of argon atoms and the electron density in this region are considered to be about the same as those of the center portion 22d of the active region 22a.

A point were the distance is 0.31 μm is a point where a distance a2 measured from the boundary B is 0.19 μm. The concentration of argon atoms at this point is equal to a first concentration which is such a concentration that the electron density at this point is equal to the electron density E_{D} in the center portion 22d.

In other words, the concentration of argon atoms is the first concentration at the position away from the boundary B by the distance a2, and the electron density in the active region 22a at this position is the same as the electron density in the center portion 22d of the active region 22a. Moreover, the electron density becomes lower than the electron density E_{D} in the center portion 22d at a point where the concentration of argon atoms is higher than the first concentration. The distance a2 where the concentration of argon atoms diffused from the element isolation region 22b into the active region 22a is equal to the first concentration is referred below to as second distance. In the example of FIG. 7, the concentration of argon atoms which provides the same electron density as the electron density E_{D} in the center portion 22d at the second distance a2 is about 1×19¹⁴ cm⁻³.

In the embodiment, the drain electrode 44 is arranged not to overlap the region of the active region 22a where the electron density is low, by setting the aforementioned first distance a1 to be greater than the second distance a2, and the electric field concentration to the drain electrode 44 is thereby prevented.

The inventors of the present application conducted research on whether the withstand voltage of the field effect transistor is actually improved by setting the first distance a1 to be greater than the second distance a2 in this manner.

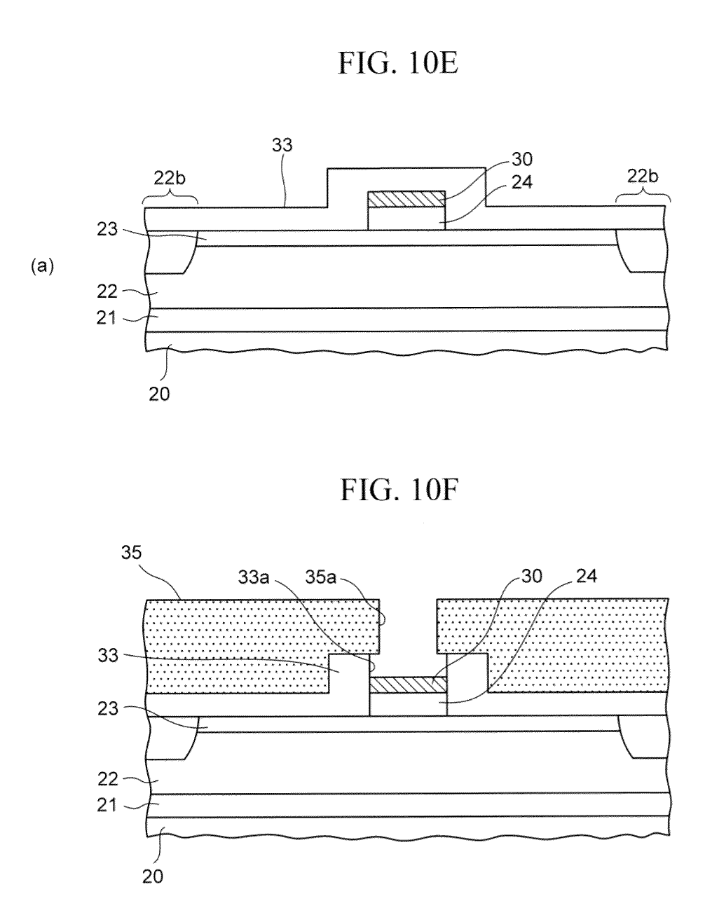

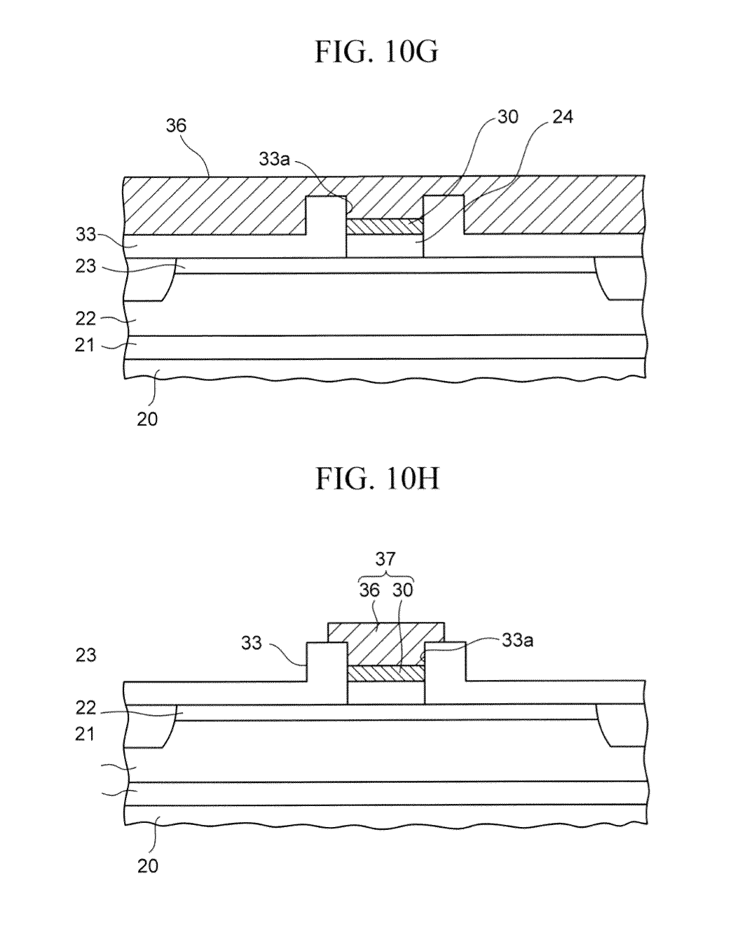

Results of this research are illustrated in FIGS. 8A and 8B.

In this research, for each of a plurality of field effect transistors set to an off state by setting the gate voltage to 0 V, relationships between a drain voltage Vd and a drain current Id of the field effect transistor is examined.

Note that FIG. 8A is a result of a comparative example in which the end portions 3a of the drain electrode 3 are provided on the element isolation region 1b as illustrated in FIG. 1.

Meanwhile, FIG. 8B is a result of the case where, the end portions 44a of the drain electrode 44 are set back from the boundary B between the active region 22a and the element isolation region 22b, and the first distance a1 is set to be greater than the second distance a2 as in the present embodiment.

As indicated by the dotted-line circles X of FIG. 8A, in the comparative example, there is a transistor in which the drain current Id sharply increases when the drain voltage Vd increases. This means that the withstand voltage is deteriorated due to the avalanche breakdown.

On the other hand, in the present embodiment illustrated in FIG. 8B, there is no transistor in which the drain current Id sharply increases like the transistor in the comparative, example. From this, it is found that setting the first distance a1 to be greater than the second distance a2 is effective to increase the withstand voltage of the field effect transistor.

Since it is difficult to exactly align the layers in manufacturing of the semiconductor device, the aforementioned first distance a1 is preferably determined in consideration of an alignment error as described below.

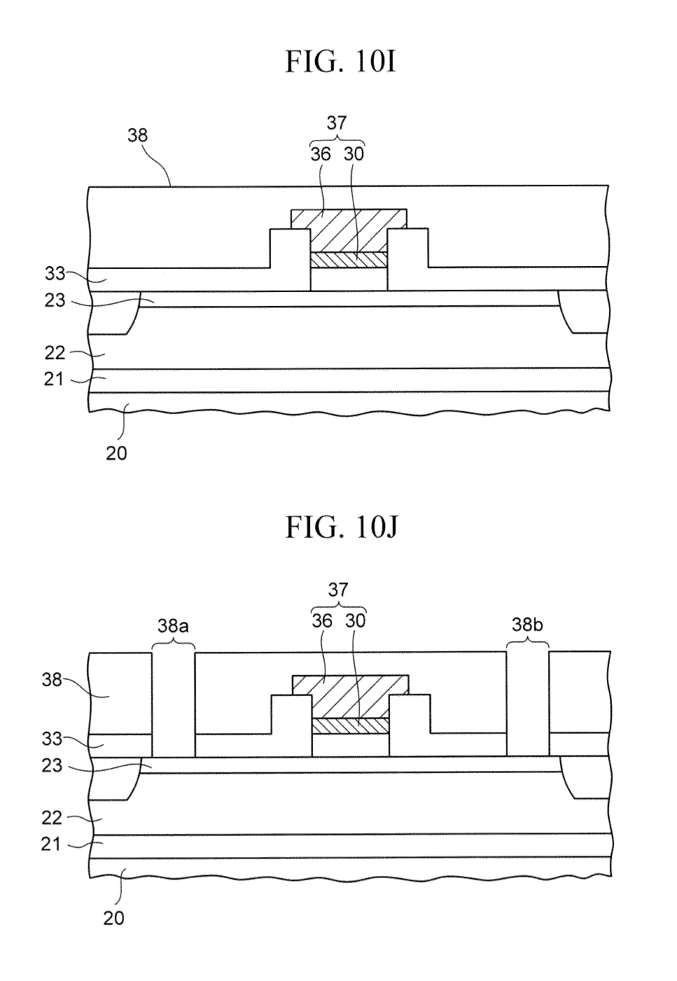

FIG. 9 is a plan view illustrating displacement between the element isolation region 22b and the drain electrode 44.

The example of FIG. 9 illustrates the case where an alignment error Δ exists between the element isolation region 22b and the drain electrode 44. The alignment error Δ is a maximum value of displacement which can occur between the element isolation region 22b and the drain electrode 44 in the manufacturing of the semiconductor device. The element isolation region 22b is displaced to the dotted line Y of FIG. 9 when the alignment error Δ occurs.

In this case, it is preferable to design the semiconductor device in such a way that the difference (a1−a2) between the aforementioned first distance, a1 and the second distance a2 are set to be greater than the alignment error Δ in consideration of the alignment error Δ. The first distance a1 between the boundary B and the end portion 44a of the drain electrode 44 is thereby surely set to be greater than the aforementioned second distance, a2 even when the element isolation region 22b and the drain electrode 44 are displaced from each other, and the withstand voltage, of the transistor can be surely improved.

For example, since the second distance a2 is 0.19 μm as described above, the first distance a1 is preferably set to a value greater than 0.69 μm (=0.19 μm+0.5 μm), for example to 6.65 μm, when the alignment error Δ is 0.5 μm.

Moreover, FIG. 9 illustrates dimensions b to q other than the dimensions described above. These dimensions are not limited to particular values and the following values can be used for example.

The interval b between the gate electrode 37 and the drain electrode 44: 3.3 μm

The width c of the gate electrode 37: 1 μm

The width d of the source electrode 43: 3 μm

The width e of the drain electrode 44: 3 μm

The length f of the drain electrode 44: 300 μm

The interval g between the gate electrode 37 and the source electrode 43: 0.7 μm

As described above, in the present embodiment, setting the aforementioned first distance a1 to be greater than the second distance a2 prevents the drain electrode 44 from overlapping the portion of the active region 22a in which the electron density is low due to the diffusion of argon. This can prevent a strong electric field from acting on the drain electrode 44 from the active region 22a, and thus improve the withstand voltage of the semiconductor device 50.

Note that, in second to fifth embodiments to be described later, the withstand voltage of the semiconductor device can be increased by setting the first distance a1 to be greater than the second distance a2 as described above.

Next, description is given of a method of manufacturing the semiconductor device according to the present embodiment.

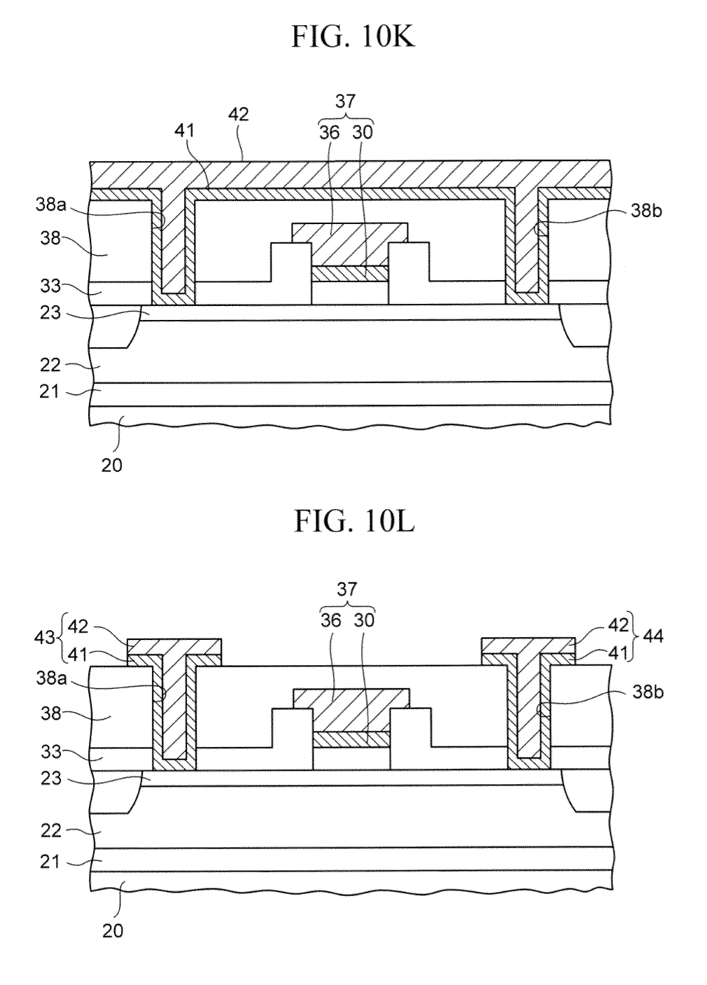

FIGS. 10A to 10N are cross-sectional views of the semiconductor device, in the course of manufacturing thereof according to the present embodiment.

First, as illustrated in FIG. 10A, a p-type silicon substrate which is doped with boron at a concentration of 8×10¹⁹ cm⁻³±8×10¹⁸ cm⁻³ and which has a thickness of about 645 μm is prepared as a semiconductor substrate 20. Note that a non-doped silicon substrate may be used as the semiconductor substrate 20.

Next, a buffer layer 21, the channel layer 22, the electron supplying layer 23, and a cap layer 24 are formed on the semiconductor substrate 20 in this order by using a Metal Organic Vapor Phase Epitaxy (MOVPE) method.

Materials and thicknesses of these layers are riot particularly limited. In the present embodiment, an AlGaN layer which has a thickness of about 100 nm to about 2000 nm and whose aluminum composition ratio is 20% or more and less than 100% is formed as the buffer layer 21.

The buffer layer 21 has a function of achieving lattice matching between the semiconductor substrate 20 and the channel layer 22. Films having such a function also include a stacked film formed by alternately stacking a plurality of AlN layers and a plurality of GaN layers. Moreover, an AlₓGa₍₁₋ₓ₎N (0<x=1) layer whose aluminum composition ratio decreases upward as the distance from the semiconductor substrate 20 increases may be formed as the buffer layer 21.

An i-type GaN layer having a thickness of about 100 nm to about 1200 cm can be formed as the channel layer 22. Note that the channel layer 22 is an example of the nitride semiconductor layer as described above.

Moreover, the electron supplying layer 23 is a layer for generating a two-dimensional electron gas by inducing electrons in the channel layer 22 therebelow. For example, an AlGaN layer which has a thickness of 5 nm to 40 nm and whose aluminum composition ratio is 10% to 30% can be formed as the electron supplying layer 23.

The cap layer 24 is, for example, a p-type GaN layer which is doped with Mg at a concentration of 1×10¹⁹ cm⁻³ to 4×10¹⁹ cm⁻³ and which has a thickness of 10 nm to 300 nm.

Next, description is given of steps performed to obtain a cross-sectional structure illustrated in FIG. 10B.

First, a silicon nitride layer having a thickness of 5 nm to 100 nm is formed on the cap layer 24 as a through film 25 for ion implantation, by a plasma CVD (Chemical Vapor Deposition) method.

Thereafter, a photoresist is applied onto the through film 25 and is then exposed to light and developed to form a first resist layer 26 having a thickness of about 0.0 μm to 3 μm.

Next, while using the first resist layer 26 as a mask, ions of inert atoms 27 such as argon are ion-implanted in a portion of the channel 22 which is not covered with the first resist layer 26.

In the portion of the channel layer 22 in which the inert atoms 27 are introduced in this manner, a crystal of gallium nitride is destroyed and the element isolation region 22b is formed. Note that a portion of the channel layer 22 other than the element isolation region 22b in which no inert atoms 27 are introduced is served as the active region 22a.

Conditions of the ion implantation are not particularly limited. In the present embodiment, the ion implantation is performed in two operations. For example, conditions, where the acceleration energy is 140 keV to 200 KeV, the dose amount is 3×10^{—}cm⁻² to 7×10¹³ cm⁻², and the tilt angle is 4° to 10° can be employed as conditions for the first ion implantation operation. Moreover, for example, conditions where the acceleration energy is 50 keV to 120 Key, the dose amount is 7×10¹² cm⁻² to 2×10¹³ cm⁻², and the tilt angle is 4° to 10° can be employed as the conditions for a second can implantation operation.

Thereafter, the through film 25 and the first resist layer 26 are removed.

Subsequently, as illustrated in FIG. 10C, a titanium nitride layer having a thickness of 20 nm to 150 nm is formed on the cap layer 24 as a first metal layer 30, by a sputtering method.

Next, as illustrated in FIG. 10D, a second resist layer 31 is formed on the first metal layer 30. Then, the cap. layer 24 and the first metal layer 30 are dry-etched with the second resist layer 31 being used as a mask, and the electron supplying layer 23 is thereby exposed beside the second resist layer 31.

An etching gas used in the dry etching is not particularly limited. In the embodiment, a chlorine-based gas or a SFₓ-based gas is used as the etching gas.

Thereafter, the second resist layer 31 is removed.

Subsequently, as illustrated in FIG. 10E, a silicon nitride layer having a thickness of 20 nm to 500 nm are formed on the electron supplying layer 23 and the first metal layer 30 by a plasma CVD method. This silicon nitride layer is used as the protection insulating layer 33.

The protection insulating layer 33 is not limited to the silicon nitride layer. A silicon oxide layer or a stacked film of a silicon nitride layer and a silicon oxide layer may be formed as the protection insulating layer 33.

Furthermore, the protection insulating layer 33 may be formed by a thermal CVD method or an Atomic layer Deposition (ALD) method instead of the plasma CVD method.

Next, description is given of steps performed to obtain a cross-sectional structure illustrated in FIG. 10F.

First, a photoresist is applied onto the protection insulating layer 33 and is then exposed to light and developed to form a third resist layer 35 including a hole 35a at a position above the first metal layer 30.

Next, the protection insulating layer 33 is wet-etched through the hole 35a by using a hydrogen fluoride solution as an etchant, and an opening 33a is formed in the protection insulating layer 33 at a position above the first metal layer 30.

Thereafter, the third resist layer 35 is removed.

Subsequently, as illustrated in FIG. 10G, a gold layer is formed on the protection insulating layer 33 as a second metal. layer 36 by a Physical Vapor Deposition (PVD) method, and the opening 33a is completely filled with the second metal layer 36.

The second metal layer 36 is not limited to the gold layer. Any of gold, nickel, cobalt, tantalum, platinum, tungsten, ruthenium, Ni₃Si, and palladium can be used as the material of the second metal layer 36. Moreover, titanium nitride or tantalum nitride rich in nitrogen or TaC rich in carbon can be used as the material of the second metal layer 36.

Thereafter, as illustrated in FIG. 10H, the second metal layer 36 is patterned by dry etching using a not-illustrated resist pattern as a mask, and is left only in the opening 33a and a portion surrounding the opening 33a. The second metal layer 36 left in the opening 33a is served as the gate electrode 37 together with the first metal layer 30 therebelow.

An etching gas used in this dry etching is not limited to a particular gas. In the embodiment, a chlorine-based gas is used as the etching gas.

Next, as illustrated in FIG. 10I, a silicon oxide layer having a thickness of about 100 nm to about 1500 nm is formed on the protection insulating layer 33 and the gate electrode 37 as an inter-layer insulating layer 38 by a spin coating method. In the spin coating method, a liquid raw material of silicon oxide flows on the surface of the protection insulating layer 33. Accordingly, the surface of the inter-layer insulating layer 38 is less likely to be uneven. Note that the inter-laver insulating layer 38 may be formed by a CVD method and, after that, the surface of the inter-layer insulating layer 38 may be flattened by a CMP (Chemical Mechanical Polishing) method.

Then, as illustrated in FIG. 10J, first and second holes 38a and 38b each having a depth reaching the electron supplying layer 23 are formed by dry-etching the protection insulating layer 33 and the inter-layer insulating layer 38 with a not-illustrated resist pattern being used as a mask.

Conditions of this dry etching are not particularly limited. For example, the dry etching can be performed by supplying an etching gas containing any of CF₄, SF₆, CHF₃, and fluorine into a parallel plate etching equipment and setting the substrate temperature to 25° C. to 200° C., the pressure to 10 mTorr to 2 Torr, and the RF power to 10W to 400W.

Next, as illustrated in FIG. 10K, a titanium nitride layer having a thickness of 1 nm to 100 nm is formed in the first and second holes 38a and 38b and on the inter-layer insulating layer 38, as the underlying conductive layer 41 by a PVD method. Furthermore, an aluminum layer is formed on the underlying conductive layer 41 as a conductive layer 42 by a PVD method, and the first and second holes 38a and 38b are completely filled with the conductive layer 42.

Since the work function of the titanium nitride layer formed as the underlying conductive layer 41 is low, the underlying conductive layer 41 and the electron supplying layer 23 form ohmic contact and the resistance therebetween can be reduced. Materials with such a low work function also include aluminum, titanium, tantalum, tantalum nitride, zirconium, TaC, NiSi₂, and silver, and a conductive layer using any of these as the material can be formed as the underlying conductive layer 41.

Next, as illustrated in FIG. 10L, the underlying conductive layer 41 and the conductive layer 42 are patterned to leave these conductive layers in the first and second holes 38a and 38b and portions surrounding the holes 38a and 38b, as the source electrode 43 and the drain electrode 44.

Note that aluminum spikes are formed in the conductive layer 43 using aluminum as the material, and these spikes penetrate the underlying conductive layer 41 and reach the electron supplying layer 23 in some cases. Accordingly, the source electrode 43 and the drain electrode 44 are preferably annealed after the formation of these electrodes to eliminate these aluminum spikes.

For example, this annealing is performed in a nitrogen atmosphere under conditions where the substrate temperature is 550° C. to 650° C. and the processing time is equal to or shorter than 180 seconds. The annealing may be performed in an atmosphere of any of a noble gas, oxygen, ammonium, and hydrogen, instead of the nitrogen atmosphere.

Then, as illustrated in FIG. 10M, a silicon oxide layer having a thickness of 100 nm to 1500 nm is formed on the inter-layer insulating layer 38, the source electrode 43, and the drain electrode 44 by a spin coating method, and this silicon oxide layer is used as a protection insulating layer 46. Note that the protection insulating layer 46 may be formed by a CVD method instead of the spin coating method.

Thereafter, although steps of forming openings for leading out the gate electrode 37, the source electrode 43, and the drain electrode 44 in the inter-layer insulating layer 38 and the protection insulating layer 46 are performed, details of these steps are omitted.

Thus, the basic structure of the semiconductor device 50 according to the present embodiment is completed.

In the semiconductor device 50, the withstand voltage of the transistor can be increased by setting the distance a1 (see FIG. 5B) between the boundary B and the end portion 44a to be greater than the aforementioned second distance a2 in the formation of the drain electrode 44 in the step of FIG. 10L.

### SECOND EMBODIMENT

In a second embodiment, a current taken out from a source electrode is increased compared to that in the first embodiment.

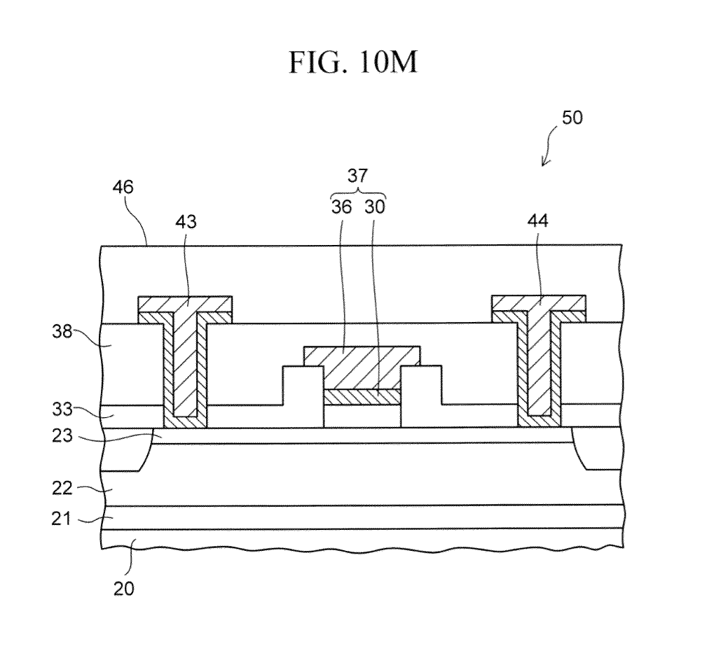

FIG. 11 is a plan view of a semiconductor device according to the present embodiment. Note that elements in FIG. 11 which are the same as those described in the first embodiment are denoted by the same reference numerals as those in the first embodiment, and description thereof is omitted below.

A semiconductor device 51 according to the present embodiment is, as in the first embodiment, a field effect transistor using a nitride semiconductor layer such as a gallium nitride layer as a channel layer 22.

In the semiconductor device 51, a source electrode 43 is extended compared to that in the first embodiment to be located on an element isolation. region 22b. Other configurations of the present embodiment are the same as those of the first embodiment.

As in the first embodiment, an active region 22a is rectangular, and has a first edge 22e and a second edge 22f which are opposite to each other at a boundary B. The extended source electrode 43 crosses the edges 22e and 22f and extends to the channel layer 22.

This increases the contact area between the active region 22a and the source electrode 43, and thereby reduces the resistance therebetween. Accordingly, the current taken out from the source electrode 43 can be increased compared to that in the first embodiment.

Note that values of dimensions a1 and b to g illustrated in FIG. 11 are not particularly limited and the following values can be used for example.

The first distance a1: 6.65 μm

The interval b between the gate electrode 37 and the drain electrode 44: 3.3 μm

The width c of the gate electrode 37: 1 μm

The width d of the source electrode 43: 3 μm

The width e of the drain electrode 44: 3 μm

The length f of the drain electrode 44: 300 μm

The interval g between the gate electrode 37 and the source electrode 43: 0.7 μm

### THIRD EMBODIMENT

In a third embodiment, electric field concentration in the end portions of a drain electrode is suppressed as follows.

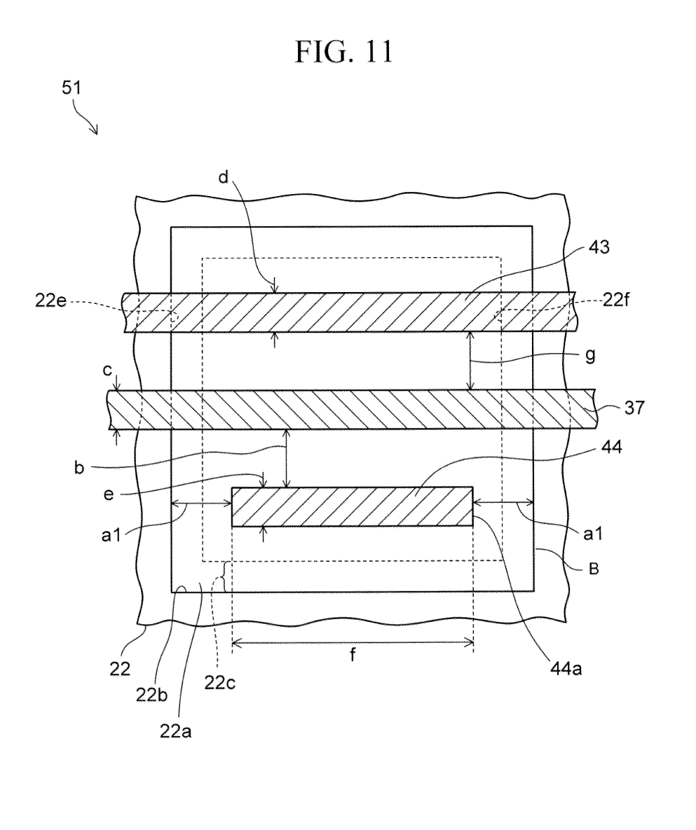

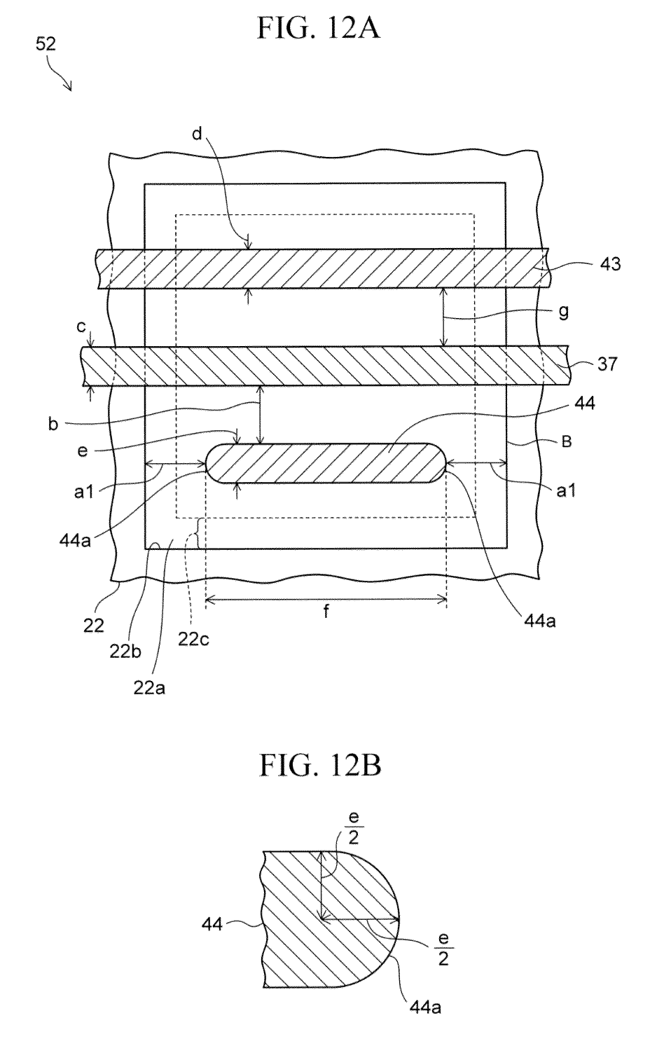

FIG. 12A is a plan view of a semiconductor device according to the present embodiment. Note that elements in FIG. 12A which are the same as those described in the first and second embodiments are denoted by the same reference numerals as those in the first and second embodiments, and description thereof is omitted below.

As in the first and second embodiments, a semiconductor device 52 according to the embodiment is a field effect transistor using a nitride semiconductor layer such as a gallium nitride layer as a channel layer 22.

In the semiconductor device 52, end portions 44a of a drain electrode 44 are round in a plan view. Other configurations of the embodiment are the same as those of the second embodiment.

In the case where sharp corners exist in the end portions 44a in the plan view, the electric field concentrate at the corners and the withstand voltage of the field effect transistor decreases.

In the present embodiment, such corners are eliminated by making the end portions 44a round, and the concentration of electric field in the end portions 44a is thereby suppressed. This can suppress decrease in the withstand voltage of the field effect transistor due to electric field concentration in the end portions 44a.

Note that values of dimensions a1 and b to g illustrated in FIG. 12A are not limited to particular values and the following values can be used for example.

The first distance a1: 6.65 μm

The interval b between the gate electrode 37 and the drain electrode 44: 3.3 μm

The width c of the gate electrode 37: 1 μm

The width d of the source electrode 43: 3 μm

The width e of the drain electrode 44: 3 μm

The length f of the drain electrode 44: 300 μm

The interval g between the gate electrode 37 and the source electrode 43: 0.7 μm

FIG. 12B is an enlarged plan view of the end portion 44a of the drain electrode 44.

The shape of the end portion 44a is not limited to a particular shape as long as the shape is a round shape with no corners. In this example, the end portion 44a is formed in a semi-circular shape whose radius is equal to half of the width e.

### FOURTH EMBODIMENT

In a fourth embodiment, a drain current is increased compared to those in the first to third embodiments.

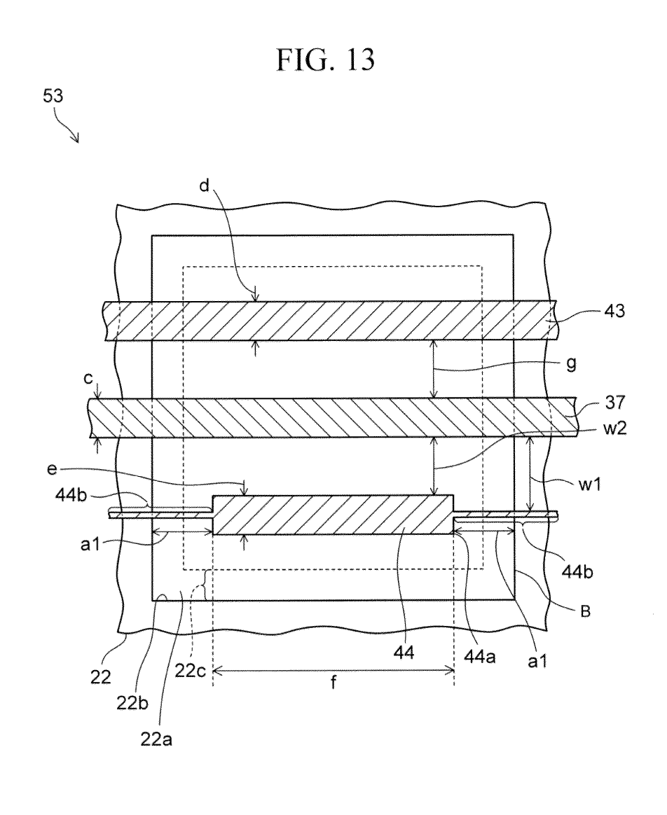

FIG. 13 is a plan view of a semiconductor device according to the present embodiment. Note that elements in FIG. 13 which are the same as those described in the first to third embodiments are denoted by the same reference numerals as those in the first to third embodiments, and description thereof is omitted below.

As in the first to third embodiments, a semiconductor device 53 according to the present embodiment is a field effect transistor using a nitride semiconductor layer such as a gallium nitride layer as a channel layer 22.

In the semiconductor device 53, extended portions 44b are provided in the end portions 44a of a drain electrode 44. Other configurations of the present embodiment are the same as those of the second embodiment.

The extended portion 44b extends from the end portion 44a to an element isolation region 22b. A first interval W1 between the gate electrode 37 and the extended portion 44b is greater than a second interval W2 between the gate electrode 37 and the drain electrode 44.

The drain current can be taken out not only from the drain electrode 44 but also from the extended portions 44b by providing the extended portions 44b in this manner. Accordingly, it is possible to increase the drain current. compared to those in the first to third embodiments.

Moreover, when a potential difference between the gate electrode 37 and the drain electrode 44 is Vd, an electric field E1 generated between the gate electrode 37 and the extended portion 44b is Vd/W1, and an electric field E2 generated between the gate electrode 37 and the drain electrode 44 is Vd/W2.

Since the first interval W1 is set to be greater than the second interval W2 in the present embodiment as described above, the electric field E1 becomes weaker than the electric field E2. This can prevent the electric field E1 from being strongly concentrated in the extended portion 44b and prevent occurrence of avalanche breakdown near the extended portion 44b.

Note, that values of dimensions a1, W1, W2, and c to g illustrated in FIG. 13 are not particularly limited and the following values can be used for example.

The first distance a1: 6.65 μm

The first interval W1: 4.3 μm

The second interval W2: 3.3 μm

The width c of the gate electrode 37: 1 μm

The width d of the source electrode 43: 3 μm

The width e of the drain electrode 44: 3 μm

The length f of the drain electrode 44: 300 μm

The interval g between the gate electrode 37 and the source electrode 43: 0.7 μm

### FIFTH EMBODIMENT

In the present embodiment, a leak current of a field effect transistor is reduced compared to those in the first to fourth embodiments as described below.

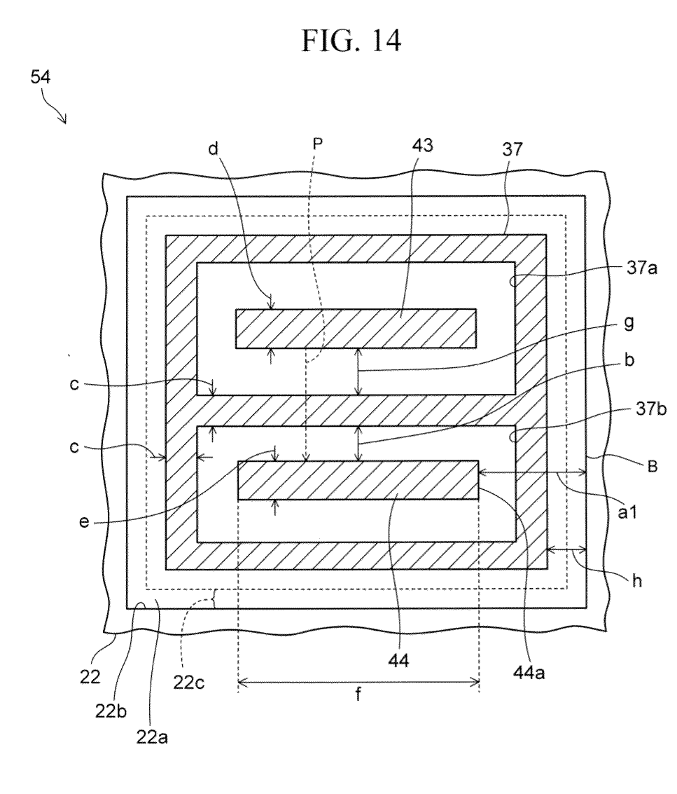

FIG. 14 is a plan view of a semiconductor device according to the embodiment. Note that elements in FIG. 14 which are the same as those described in the first to fourth embodiments are denoted by the same reference numerals as those in the first to fourth embodiments, and description thereof is omitted below.

As in the first to fourth embodiments, a semiconductor device 54 according to the present embodiment is a field effect transistor using a nitride semiconductor layer such as a gallium nitride layer as a channel layer 32.

In the semiconductor device 54, a gate electrode 37 is formed in a portion of an active region 22a which is spaced away from an element isolation region 22b, so that the gate electrode 37 is prevented from overlapping the boundary B of the active region 22a and the element isolation region 22b.

Furthermore, the gate electrode 37 has a first opening 37a and a second opening 37b which are provided with an interval therebetween. Among them, the first opening 37a includes a source electrode 43 therein in a plan view. The second opening 37b includes a drain electrode 44 therein in the plan view.

Here, defects occur at the boundary B when ions of inert atoms such as argon are ion-implanted into the element isolation region 22b. This defects cause trap assisted tunneling. Accordingly, when the boundary B and the gate electrode 37 overlap each other in the plan view, a leak current flows from the gate electrode 37 to the channel layer 22 due to the trap assisted tunneling.

Since the gate electrode 37 does not overlap the boundary B in the present embodiment, it is possible, to suppress occurrence of the leak current below the gate electrode 37 as in the above, and thereby improve the reliability of the semiconductor device 54.

Furthermore, since the source electrode 43 and the drain electrode 44 are surrounded by the openings 37a, 37b of the gate electrode 37, an arbitrary current path P extending from the source electrode 43 to the drain electrode 44 inevitably overlaps the gate electrode 37.

Accordingly, it is possible to prevent a current from flowing through the current path P below the gate electrode 37 when a gate voltage is set to a low level and the transistor is turned off, and to suppress the leak current flowing from the source electrode 43 to the drain electrode 44.

Note that values of dimensions a1 and b to h illustrated in FIG. 14 are not particularly limited and the following values can be used for example.

The first distance a1: 6.65 μm

The interval b between the gate electrode 37 and the drain electrode 44: 3.3 μm

The width c of the gate electrode 37: 1 μm

The width d of the source electrode 43: 3 μm

The width e of the drain electrode 44: 3 μm

The length f of the drain electrode 44: 300 μm

The interval g between the gate electrode 37 and the source electrode 43: 0.7 μm

The interval h between the gate electrode 37 and the element isolation region 22b: 1.75 μm

All examples and conditional. language provided herein are intended for the pedagogical purpose of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention has been described in detail, it should be understood that the various changes, substitutions, and alterations could be made hereto without departing from the spirit and scope of the invention.

What is claimed is:

1. A semiconductor device comprising:
a substrate;
a nitride semiconductor layer formed over the substrate and including an active region and an element isolation region, inert atoms being introduced into the element isolation region;
a source electrode formed over the nitride semiconductor layer in the active region;
a gate electrode formed over the nitride semiconductor layer in the active region away from the source electrode; and
a drain electrode formed over the nitride semiconductor layer in the active region away from the gate electrode, the drain electrode including an end portion provided away from a boundary between the element isolation region and the active region by a first distance, wherein
the first distance is greater than a second distance, the second distance being a distance where a concentration of the inert atoms diffused from the element isolation region into the active region becomes a first concentration, and an electron density in the active region at a position where the concentration of the inert atoms is higher than the first concentration is lower than an electron density in a center portion of the active region.

2. The semiconductor device according to claim 1, wherein
the active region has a first edge and a second edge opposite to each other at the boundary between the active region and the element isolation region, and
the source electrode crosses the first edge and the second edge and extends onto the nitride semiconductor layer in the element isolation region.

3. The semiconductor device according to claim 1, wherein the end portion of the drain electrode is round in a plan view.

4. The semiconductor device according to claim 1, further comprising:
an extended portion provided in the end portion of the drain electrode, wherein
the extended portion extends from the end portion to the element isolation region.

5. The semiconductor device according to claim 4, wherein a first interval between the gate electrode and the extended portion is greater than a second interval between the gate electrode and the drain electrode.

6. The semiconductor device according to claim 1, wherein a difference between the first distance and the second distance is greater than an alignment error between the element isolation region and the drain electrode.

7. The semiconductor device according to claim 1, wherein an electron density in the active region at a position away from the boundary by the second distance, is the same as the electron density in the center portion of the active region.

8. A semiconductor device comprising:
a substrate;
a nitride semiconductor layer formed over the substrate and including an active region and an element isolation region, inert atoms being introduced into the element isolation region;
a source electrode formed over the nitride semiconductor layer in the active region;
a drain electrode formed over the nitride semiconductor layer in the active region away from the source electrode, the drain electrode including an end portion provided away from a boundary between the element isolation region and the active region by a first distance; and
a gate electrode formed over the nitride semiconductor layer in the active region away from the element isolation region and including a first opening and a second opening, the source electrode being in the first opening, the second opening being provided away from the first opening, the drain electrode being in the second opening, wherein
the first distance is greater than a second distance, the second distance being a distance where a concentration of the inert atoms diffused from the element isolation region into the active region becomes a first concentration, and an electron density in the active region at a position where the concentration of the inert atoms is higher than the first concentration is lower than an electron density in a center portion of the active region.

9. The semiconductor device according to claim 8, wherein a difference between the first distance and the second distance is greater than an alignment error between the element isolation region and the drain electrode.

10. The semiconductor device according to claim 8, wherein an electron density in the active region at a position away from the boundary by the second distance is the same as the electron density in the center portion of the active region.

11. A method of manufacturing a semiconductor device comprising:
forming a nitride semiconductor layer over a substrate;
forming an element isolation region by implanting ions of inert atoms into the nitride semiconductor layer, a portion of the nitride semiconductor layer other than the element isolation region being an active region;
forming a source electrode over the nitride semiconductor layer in the active region;
forming a gate electrode over the nitride semiconductor layer in the active region away from the source electrode;
forming a drain electrode over the nitride semiconductor layer in the active region away from the gate electrode, the drain electrode including an end portion provided away from a boundary between the element isolation region and the active region by a first distance, wherein
in the forming the drain electrode, the first distance is greater than a second distance, the second distance being a distance where a concentration of the inert atoms diffused from the element isolation region into the active region becomes a first concentration, and an electron density in the active region at a position where the concentration of the inert atoms is higher than the first concentration is lower than an electron density in a center portion of the active region.
